(19) United States
(12) Patent Application Publication
(10) Pub. No.: US 2021/0013000 A1
(43) Pub. Date: Jan. 14, 2021

(54) POROUS CARBONACEOUS VACUUM CHAMBER LINERS

(71) Applicant: ENTEGRIS, INC., Billerica, MA (US)

(72) Inventors: Troy SCOGGINS, Decatur, TX (US); Rex G. SHEPPARD, Decatur, TX (US); Abuagela H. RASHED, Denton, TX (US); Amelia H.C. HART, Fort Worth, TX (US)

(21) Appl. No.: 16/923,724

(22) Filed: Jul. 8, 2020

Related U.S. Application Data
(60) Provisional application No. 62/871,984, filed on Jul. 9, 2019.

(51) Int. Cl. H01J 37/30; H01J 37/317; H01J 37/18

(52) U.S. Cl. CPC H01J 37/3002; H01J 2237/31705; H01J 37/18; H01J 37/3171

(57) ABSTRACT

Described are porous protective liners for use in a vacuum chamber, the liners being made of inorganic carbonaceous material and having a porous surface, preferably with the pores being of an open-pore structure.

### FIELD OF THE INVENTION

The invention relates to porous protective liners for use in a vacuum chamber, the liners being made of inorganic carbonaceous material and having a porous surface, preferably with the pores being of an open-pore structure.

### BACKGROUND

Vacuum chambers are useful for processing materials and devices in a vacuum. One process that involves a vacuum chamber is ion implantation, by which a surface of a workpiece is exposed to ions, causing the ions to penetrate the surface.

During processing within a vacuum chamber, an interior space and atmosphere of the vacuum chamber must be at a low pressure and will contain ions that are useful for the desired processing step. The ion implantation process requires a very high level of purity of the useful materials present in the processing atmosphere. The atmosphere should be as free as possible from any impurities or contaminants that are not either an ion capable of being implanted into the substrate, or a related material that is otherwise useful or required for the process.

Unfortunately, during use of a vacuum chamber for processing, contaminants and impurities are typically introduced into or generated within the vacuum chamber. For example, during an implantation process, particle-sized contaminants can be generated and may accumulate within the vacuum chamber. To reduce or desirably eliminate this effect, different types of inert protective liners are placed within vacuum chambers to reduce or minimize particle generation during an implantation process.

### SUMMARY

The present description relates to liners for protecting sidewalls or other interior surfaces of vacuum chambers, and related methods. A liner, which may optionally be removable and replaceable, is located at the interior of the vacuum chamber to cover surfaces of sidewalls, to reduce the generation of particle contaminants within the vacuum chamber during use. The liner has a surface that is exposed to the interior space of the vacuum chamber, and that is made of a porous inorganic carbonaceous material that preferably includes an open cell structure. To reduce particle contamination within the vacuum chamber, the liner can be placed at interior surfaces of the vacuum chamber that are exposed to a workpiece or ions (e.g., an ion beam). The liner can include a surface that is made of a material and that has a structure to: i) resist the formation or release of particle contaminants in the event that an ion collides with a surface of the liner during use of the vacuum chamber; ii) removes particle contaminants from a bulk atmosphere of a vacuum chamber, such as by capturing particle contaminants that, during operation of the vacuum chamber, contact the liner; or iii) preferably does both of these.

In one aspect, the invention relates to an apparatus that includes a vacuum chamber and a liner that has a surface exposed to an interior of the vacuum chamber, with the surface being made of porous inorganic carbonaceous material.

In another aspect, the invention relates to a vacuum chamber that includes an interior and a liner at the interior. The liner has a surface that is exposed to the interior and the surface is made of porous inorganic carbonaceous material.

In another aspect, the invention relates to a method of using an apparatus having a vacuum chamber that includes a liner. The method includes: generating an ion beam within the vacuum chamber, or generating debris particles within the vacuum chamber, or generating an ion beam and debris particles within the vacuum chamber. The liner has a surface exposed to an interior space of the vacuum chamber and the surface is made of porous inorganic carbonaceous material. During the method of using the apparatus, the ion beam or the debris particles contact the surface of the liner.

### BRIEF DESCRIPTION OF THE FIGURES

FIGS. 1A and 1B are photographs of porous surfaces as described.

FIGS. 2A and 2B are photographs of porous surfaces as described.

FIGS. 3A and 3B are photographs of porous surfaces as described.

FIG. 3C is a photograph of a fiber of a porous surface as described.

FIG. 4 is a diagram of an apparatus as described that includes a vacuum chamber having a liner of the present description.

### DETAILED DESCRIPTION

The following description relates to vacuum chambers that contain a low pressure (“evacuated”) interior for processing a workpiece in a high vacuum environment. The description also relates to methods of using a vacuum chamber as described.

The vacuum chamber can be used for processing a workpiece that is a semiconductor material (e.g., semiconductor wafer), a microelectronic device, or a microelectronic device precursor, such as to deposit a material at a surface of the workpiece or to implant a material at a surface of the workpiece. The vacuum chamber can be included as part of a larger apparatus such as an ion implantation device that includes the vacuum chamber supplied by a supply of ions for implantation, e.g., in the form of an ion beam directed into the vacuum chamber. One non-limiting example of a vacuum chamber as part of a larger device or system is an ion implantation device for implanting ions, e.g., as a dopant, into material at a surface of a semiconductor substrate.

According to the present description, the vacuum chamber includes sidewalls that define an interior of the vacuum chamber. One or more liners, which may optionally be removable and replaceable, are located at the interior of the vacuum chamber to cover one or more of the sidewalls. The one or more liners have a liner surface that is exposed to the interior space of the vacuum chamber, e.g., to a workpiece, ions, or both. The liner surface can be made of a porous inorganic carbonaceous material having an open cell structure.

In an embodiment of the invention a vacuum chamber will be held at a low pressure, such as below 25 torr, below 5, 1, or 0.1 torr, throughout the vacuum chamber. The vacuum chamber includes a space used to contain and support a workpiece (e.g., “semiconductor wafer” or other substrate, e.g., a microelectronic device or precursor thereof) to facilitate processing of the workpiece within the vacuum chamber. The vacuum chamber may also include adjacent spaces necessary for supplying a material to the vacuum chamber for processing, such as an ion beam. As an example, an ion implantation device can include an end station, which is a location for placing and supporting a workpiece (e.g., semiconductor wafer) during implantation of ions into the workpiece. The ion implantation device also includes space for generating or supplying an ion beam and directing the ion beam into the end station. These spaces are held at low pressure during use, e.g., are part of a vacuum chamber of the ion implantation device.

Ion implantation is a standard technique for introducing conductivity-altering impurities into workpieces such as semiconductor wafers. The process is performed using an ion implantation device that includes a vacuum chamber, which includes an end station and an ion beam source. The vacuum chamber is at a very low pressure. But even at very low pressure, the vacuum chamber will contain minute amounts of undesired contaminants. The contaminants can be generated within or presented to the vacuum chamber in any of a variety of different ways, can vary in terms of their physical form (e.g., a microparticle, nanoparticle, chemical (molecular) vapor), and can be of varied chemical makeup.

The presence of contaminant particles in a vacuum chamber is detrimental to processing a workpiece. Some types of contaminants, e.g., particle contaminants, may be generated during a process that is performed in a vacuum chamber. For example, during ion doping of a semiconductor wafer, i.e., “ion implantation,” an ion from an ion beam (input) that impinges on a surface of a photoresist material on a workpiece can react with the photoresist material and cause a debris particle to be released from the photoresist and into the atmosphere of the vacuum chamber. The particle could potentially become placed on an open surface of the workpiece, at which location the particle is a contaminant. As another example, a particle contaminant can be produced within a vacuum chamber by a high energy particle such as an ion of an ion beam impinging on a material of an interior surface of the vacuum chamber, e.g., a sidewall or other functional structure. This source of particle contaminants is sometimes referred to as “ion sputtering.” The generated ion is released into the atmosphere of the vacuum chamber as a contaminant. An ion that impinges other interior surfaces of the vacuum chamber may also generate particle contaminants.

To reduce the amount of contamination in a vacuum chamber, a liner can be placed at interior surfaces of the vacuum chamber that are exposed to a workpiece or ions (e.g., an ion beam). The liner can include a surface that is made of a material and that has a structure that is effective to: i) resist the formation or release of a particle contaminant in the event that an ion impinges upon a surface of the liner during use of the vacuum chamber; ii) remove particle contaminants from a bulk atmosphere of a vacuum chamber, such as by capturing particle contaminants that, during operation of the vacuum chamber, contact the liner; or iii) preferably does both of these.

The term “liner” refers to a substantially two-dimensional sheet or membrane that has two opposed major surfaces, each extending in both a length and a width direction, with a thickness dimension between the two opposed surfaces. The magnitude of the thickness dimension is substantially less than both of the length and the width. A liner may be flexible or rigid depending on factors such as the type of material of the liner and physical features of the liner such as construction (e.g., woven or “sponge”), thickness, porosity, and pore size.

A liner as described can include at least one surface that is made of porous inorganic carbonaceous material having an open cell structure. Example liners can be of a material and structure that cause the liner to be chemically resistant under the vacuum chamber conditions, e.g., resistant to chemical change or to the release of a material particle when contacted with process materials of a process performed within the vacuum chamber. Example liners are made of a relatively inert porous inorganic carbonaceous material such as amorphous carbon, graphite, or silicon carbide, which can cause the liner to be resistant to sputtering, i.e., to the release of material particle that can become particle contaminants at an interior of a vacuum chamber. In addition to being made chemically resistant and resistant to sputtering, a liner as described can also have a surface that includes openings that are capable of capturing contaminant particles in an atmosphere of a vacuum chamber, to remove the particles from the atmosphere. Also, preferably, the porous surface can have an additional advantage, when exposed to an ion beam, of receiving a reduced number of orthogonal beam impacts.

An inorganic carbonaceous material refers to a solid material that is made of a major amount of carbon or that is substantially or primarily made of carbon, in non-organic form. The inorganic carbonaceous material can contain, for example, at least 50 weight percent carbon, or at least 60, 70, 80, 90, 95, or 99 weight percent carbon. The inorganic carbonaceous material contains a low or insignificant amount (e.g., less than 5, 1, 0.5, or 0.1 weight percent) of organic compounds made of carbon atoms covalently bonded to hydrogen, oxygen, or nitrogen atoms.

Some examples of inorganic carbonaceous materials may be made primarily of carbon atoms either an amorphous or a crystalline (e.g., graphite) form, e.g., may contain at least 90, 95, 98, or 99 atomic percent carbon in either an amorphous or a crystalline form.

Other examples of inorganic carbonaceous materials may contain primarily carbon and silicon atoms, including materials referred to commonly as silicon carbide (SiC). Useful or preferred silicon carbide materials may containing least 80, 90, 95, 98, or 99 atomic percent of a total amount of silicon and carbon, and may preferably contain a low amount or not more than an insignificant amount of other materials such as oxygen or hydrogen, e.g., less than 5, 3, 1, or 0.5 atomic percent of total oxygen and hydrogen. Example forms of silicon carbide include forms that are crystalline as well as forms that area amorphous. Example silicon carbide materials may contain from 40 to 90 atomic percent carbon, from 10 to 60 atomic percent silicon, and not more than 2 or 1 atomic percent of other materials, e.g., not more than 0.5 atomic percent oxygen, hydrogen, or a combination of oxygen and nitrogen. A porous silicon carbide material may be prepared by any method, including known methods of converting graphite to silicon carbide. By another method, a silicon carbide coating may be deposited onto a porous carbon foam, such as by chemical vapor depositions (CVD), chemical vapor infiltration (CVI), or any other related forms of deposition, followed by an oxidizing step to remove carbon.

Of these inorganic carbonaceous materials, relating to their porous physical forms, certain more specific examples include: different forms of crystalline graphite that are capable of being formed into a thin porous liner having a structure that includes open pore foam; amorphous carbon materials that are capable of being formed into a thin porous liner having a structure that includes open pore foam; silicon carbide in the form of a porous foam; and amorphous carbon and crystalline graphite materials that can be formed into fibers that can be woven, knit, or otherwise formed into a liner of porous fibrous fabric.

The liner can include at least one surface that is porous, with an open pore structure. When described herein, a “surface” of a liner having a feature of being “porous” with an open pore structure refers to an exposed surface of the liner along with a three-dimensional region of the liner that is near or very near to the exposed surface. For a purpose of considering porosity of an open pore structure of a “surface,” the three-dimensional region of the surface may be considered to extend to a depth that is very near the surface, such as a depth of 500 microns below the surface, alternately to a depth that is 700 or 1000 microns below the surface.

“Pores” of a porous surface (or throughout a thickness of a liner) may be of any effective form. Example pores may be in the form of openings having a generally rounded or curved cell structure defined by and between sidewalls (e.g., a “matrix”) composed of the carbonaceous material. Alternately, pores of a porous structure may be interstitial openings (e.g., channels, passages) present between fibers of a carbonaceous material that is woven, knitted, or the like.

A porous, open pore surface of a liner can be preferred because, without being bound by theory, a porous, open pore surface is believed to be effective to reduce the generation of particles in a vacuum chamber relative to a non-porous surface or a closed-pore surface. A surface that is porous with open pores, if exposed to a source of ions, e.g., ions in the form of an ion beam, can receive a reduced amount of ions that impact a surface that is orthogonal to the direction of movement of the ion. An ion that impacts a surface of a liner that is porous, especially with an open pore structure, is less likely to strike the surface directly at a location that extends in a plane that is orthogonal (perpendicular) to the path of the movement of the ion. The ion may instead strike a portion of the porous surface that is angled or curved relative to the path of the ion. Impacting the porous liner surface at a location of the liner that is non-orthogonal relative to the direction of motion of the ion can reduce the amount of energy transferred from the ion to the surface as a result of the collision, which can create in a reduced potential for the formation and release of a particle (debris) from the materials of the surface.

For purposes of the present description, a surface of a liner is considered to be “porous,” i.e., to include a “porous surface,” if the surface is more than slightly porous based on the porosity of the liner at the surface. A porous liner, e.g. a surface thereof, can be sufficiently porous to be capable of containing and collecting particles that circulate within a bulk atmosphere of a vacuum chamber, during use. A particle that circulates in an atmosphere of a vacuum chamber that includes a porous, open pore surface of a liner, if the particle engages the surface of the liner, may pass into a pore (“cell”) of the open pore surface and become trapped within the open cell structure. The particle is effectively isolated from (removed from) the bulk interior space of the vacuum chamber and is eliminated as a potential particle contaminant that could otherwise become located at a surface of a workpiece being processed within the vacuum chamber.

Porosity at a “surface” of a liner can be considered to be the porosity of a three-dimensional portion (volume) of the liner that includes the two-dimensional surface as well as an adjacent amount of the three-dimensional volume of the structure that is near or very near to the surface. For example, “porosity of a surface” of a liner can be measured as a porosity of a volume of the liner that is located very near the surface, such as a volume that includes the surface and a volume from the surface to a depth of 500 microns (e.g., 1000 microns) below the surface.

A “porosity” (also sometimes referred to as “void fraction”) of a three-dimensional porous structure such as a liner as described is a measure of the void (i.e. “empty”) space in the three-dimensional structure as a percentage of the total volume of the body including the void space and solid fraction. Porosity is calculated as a fraction of the volume of voids of the structure over the total volume of the structure including both the solid material of the structure and the void space within the structure. A structure that has zero percent porosity is completely solid.

By this measure, a surface of a liner can be considered to be “porous” if the surface has a porosity measured in this manner of least 18 percent, e.g., at least 20, 30, 40, 50, 60, or 70 percent. Exemplary liners can have a porosity in a range from 18, 20, 30, 40, 50, or 60 percent, up to 70 80, 90, 95, or 97 percent, measured at a surface as described, e.g., measured for a volume of the liner that extends from the surface to a depth of 500 microns, e.g., 1,000 microns below the surface. According to other examples, a liner may have a porous, open pore structure at the surface, and also extending through the entire thickness of the liner. Example thicknesses of useful or preferred liners may be in a range from 500 microns to 10,000 microns, e.g., from 1,000 up to 5,000, 7,000, 9,000 or 10,000 microns.

As used herein, an “open pore” (a.k.a. “open cell”) structure can be a porous structure of a liner (e.g., membrane, film, liner, or a portion or layer thereof) that includes a substantial amount of three-dimensional pores (openings, cells, apertures, channels, passages, or the like) that are “open” (connected) as opposed to “closed” (not connected) relative to the other pores of the structure. Each pore of an open pore structure is defined substantially by solid material of the structure, such as in the form of solid (rigid or flexible) walls of a porous foam or sponge matrix, or in the form of surfaces of fibers of a woven or knit fabric liner. Because the pores are partially but not completely enclosed by the solid material (wall or fiber surface), the pores are interconnected to each other and fluid or particles may pass from one pore to a different pore.

Examples of open pore structures include open pore sponges as well as fiber-based fabrics such as woven, non-woven, knit, felt, and other fabric-type materials made of inorganic carbonaceous fiber material. Preferred open pore structures can have at least a majority (at least 50 percent) of pores interconnected, e.g., at least 60, 70, or 80 percent of pores interconnected, so that fluid or particles (if sufficiently small) may pass between the pores, i.e., from one pore to at least one other pore. In contrast, other types of porous materials are understood to be “closed-cell”materials (e.g., “closed-cell foams”), meaning that a majority (or more, e.g., 70, 80, or 90 percent) of the pores (“cells”) are not connected to another pore, and fluid or particles cannot pass between the pores; e.g., the pores are entirely enclosed by the solid material of the structure of pore walls.

One specific example of a porous, open pore inorganic carbonaceous material useful for a liner is an open cell foam. Example foams may be made of amorphous carbon, silicon carbide, or graphite.

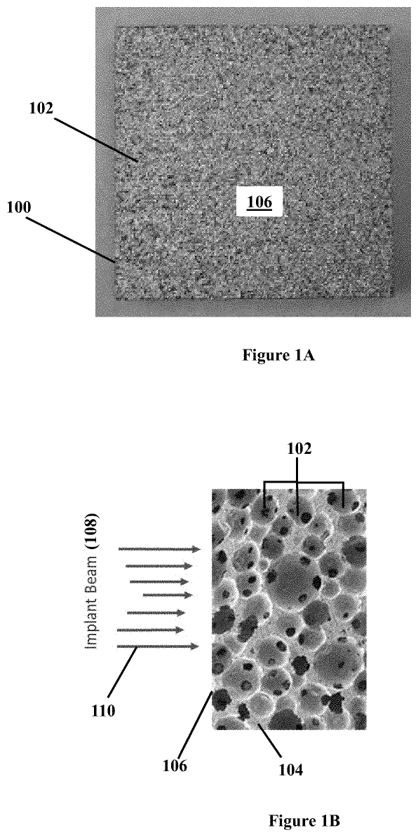

FIGS. 1A and 1B are photographs of an exemplary carbonaceous foam structure, specifically an open cell carbonaceous foam (e.g., graphite foam). As shown at the figures, foam 100 includes pores (“cells”) 102 defined by curved walls of solid matrix 104, and includes porous surface 106. Pores 102 are substantially interconnected (e.g., “open” pores) and can be present at surface 106 as well as across an entire thickness of the foam structure. The average size of the pores can be in a range from approximately 100 microns up to1000 microns (0.1 to 1 millimeter). The porosity of the illustrated foam, including porosity measured either at surface 106 or over an entire thickness of the foam, can be at least 50 percent, e.g., in a range from 50 or 60, up to (or exceeding) 80, 90, 95, or 97 percent.

As shown at FIG. 1B, during use, ion beam 108, containing ions 110, may be directed at surface 106 of foam 100, used as a liner at an interior of a vacuum chamber. Each ion 110 approaches surface 106 from a direction that is perpendicular to the general planar surface of foam 100. On a magnified scale, however, the porous surface, i.e., the surface of matrix 104, is not flat but includes many curved, rounded, and non-orthogonal locations. An ion 110 can strike a solid portion of matrix 104 at a surface that is not orthogonal to, i.e., is angled relative to the path of the ion.

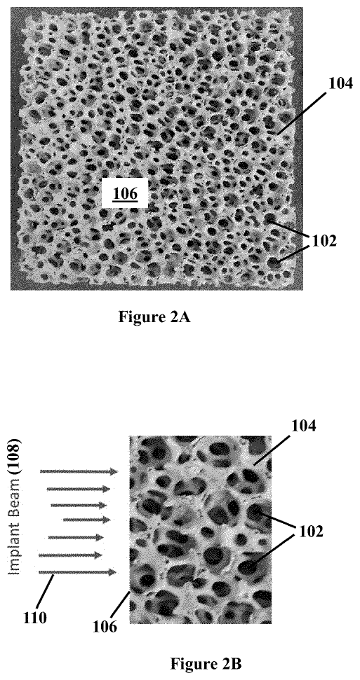

FIGS. 2A and 2B are photographs of another exemplary carbonaceous foam structure, specifically an open cell low density silicon carbide foam structure. The foam is made of silicon carbide and can have a density of below about 1 gram per cubic centimeter, e.g., below 0.8, 0.6, or 0.5 gram per cubic centimeter. As shown at the figures, foam 100 includes pores (“cells”) 102 defined by curved walls of solid matrix 104, and includes porous surface 106. Pores 102 are substantially interconnected (e.g., “open” pores) and can be present at surface 106 as well as across an entire thickness of the foam structure. The average size of the pores can be in a range from approximately 1000 microns to 5000 microns (1 to 5 millimeters). The porosity of the illustrated foam, including porosity measured either at surface 106 or over an entire thickness of the foam, can be at least 50 percent, e.g., in a range from 50 or 60, up to 90, 95, or 97 percent.

As shown at FIG. 2B, during use, ion beam 108, containing ions 110, may be directed at surface 106 of foam 100, used as a liner at an interior of a vacuum chamber. Each ion 110 approaches surface 106 from a direction that is perpendicular to the general planar surface of foam 100. On a magnified scale, however, the porous surface is not flat and includes may curved, rounded, and non-orthogonal surfaces. An ion 110 can strike at surface of solid matrix 104 at a location that is not orthogonal to, i.e., is angled relative to the path of the ion.

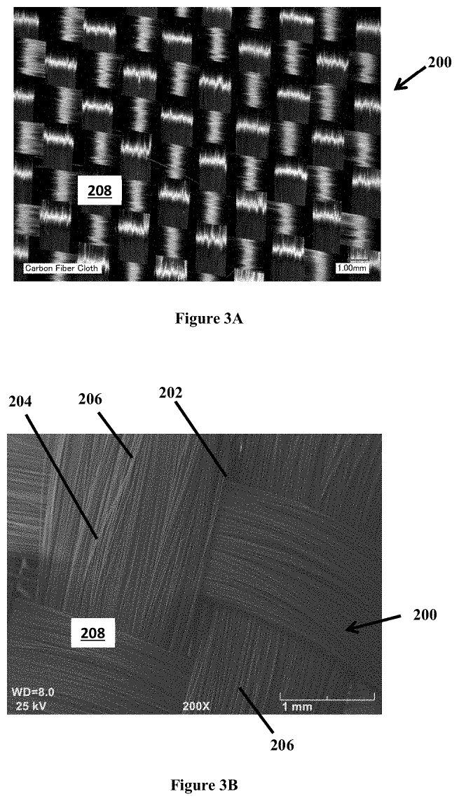

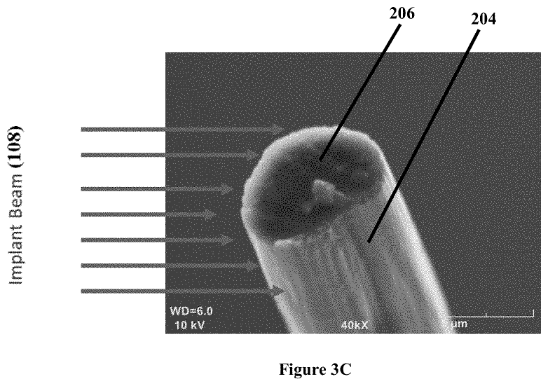

Yet another example of a liner made of inorganic carbonaceous material is shown at FIGS. 3A, 3B, and 3C, which are pictures of a woven-fabric-type liner made of carbon fiber. Liner 200 is made of fibers of inorganic carbonaceous material, e.g., amorphous carbon, graphite, or the like, and includes pores (“openings, channels, or passages”) 202 defined by curved surfaces 204 of fibers 206, and includes porous surface 208. Pores 202 are substantially interconnected (e.g., “open” pores) and can be present at surface 208 as well as across an entire thickness of the woven structure. The porosity of the illustrated fabric measured over the entire thickness of the fabric can be at least 40 percent, e.g., in a range from 40 or 50, up to or exceeding 70, 80, or 90 percent.

As shown at FIG. 3C, during use, ion beam 108, containing ions 110, may be directed at surface 208 of foam fabric liner 200, used as a liner at an interior of a vacuum chamber. Each ion 110 approaches surface 208 from a direction that is perpendicular to the general planar surface of fabric liner 200. On a magnified scale, however, the fibers that make up the porous and fibrous surface are not flat, but include many curved, rounded, and non-orthogonal surfaces. An ion 110 can strike a surface 204 of a fiber 206 of surface 208 at location at which surface 204 is not orthogonal to the path of the ion but is angled relative to the path of the ion.

The liner is generally in the form of a thin sheet or membrane having two opposed sides each having an exposed surface, the membrane having a width, a length, and a thickness that is substantially less than the length and width, and the porous carbon material being on an exposed surface. A liner can be used alone as a single material, as a protective liner placed over a sidewall of a vacuum chamber. Alternately, a liner can be one layer of a multi-layer liner that is placed to cover a sidewall. One or more additional layers of a multi-layer liner may be a base layer, such as a graphite layer, having a form that is not a porous, open cell material, such as a non-porous graphite sheet.

A liner as described can be specifically useful in connection with a vacuum chamber of an ion implanter, particularly a beam-line implanter. However, liners as described may also be useful with vacuum chambers of other systems and processes, e.g., other types of ion implantation devices, involved in semiconductor manufacturing, and that produce ions or particulate debris within a vacuum chamber, e.g., other systems and processes that involve plasma treatment, accelerated ions, or other processes performed in a vacuum chamber. Thus, the invention is not limited to the specific embodiments described and illustrated herein.

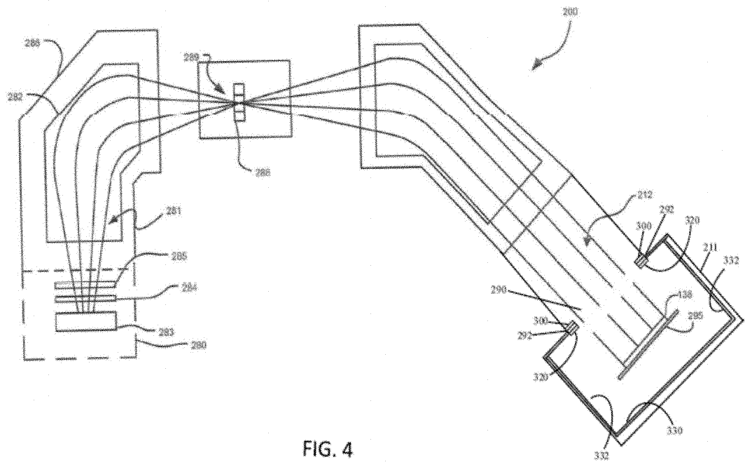

Referring to FIG. 4, illustrated is a schematic diagram of a beam-line ion implanter 200 that may provide ions for treating (e.g., “doping”) a workpiece such as a semiconductor wafer. Beam-line ion implanter 200 is one example of a variety of beam-line ion implanters that can provide ions for doping a selected material (“workpiece,” or “substrate”). Beam-line ion implanter 200 includes ion source 280 that generates ions that form ion beam 281. Implanter 200 also includes end station 211 and related ion beam handling functions (e.g., magnets, lenses, etc.), as illustrated. All of these are operated within a vacuum, or a “vacuum chamber.”

Ion source 280 includes ion chamber 283 and a gas box that contains a gas to be ionized. The gas is supplied to ion chamber 283 where the gas is ionized. This gas may be or may include, in some embodiments, As, B, P, H, N, O, He, carborane C₂B₁₀H₁₂, another large molecular compound, another noble gas, or any other precursor to a dopant ion. The ions that are formed are extracted from ion chamber 283 to form ion beam 281, which is directed between the poles of resolving magnet 282. A power supply is connected to an extraction electrode of ion source 280. Ion beam 281 passes through a suppression electrode 284 and ground electrode 285 to mass analyzer 286. Mass analyzer 286 includes resolving magnet 282 and masking electrode 288 having a resolving aperture 289. The resolving magnet 282 deflects ions in the ion beam 281 such that ions of a desired ion species pass through resolving aperture 289. Undesired ion species do not pass through the resolving aperture 289, but are blocked by the masking electrode 288.

Ions of a desired ion species pass through the resolving aperture 289 to an angle corrector magnet. The angle corrector magnet deflects ions of the desired ion species and converts the ion beam from a diverging ion beam to a ribbon ion beam 212, which has substantially parallel ion trajectories.

End station 211 is defined by multiple sidewalls, a top, a bottom, and includes beam opening 290 on sidewall 292, through which ion beam 212 passes. End station 211 supports one or more workpieces, such as workpiece 138, in the path of the ribbon ion beam 212 such that ions of the desired species are implanted into workpiece 138. End station 211 may include platen 295 to support workpiece 138. End station 211 also may include a scanner (not shown) for moving workpiece 138 perpendicular to the long dimension of the ribbon ion beam 212 cross-section, thereby distributing ions over the entire surface of workpiece 138. Although the ribbon ion beam 212 is illustrated, other embodiments may provide a spot beam.

According to the present description, end station 211 includes one or more liners as described herein, made of porous inorganic carbonaceous material having an open cell structure. As illustrated, liner 300 is located on an upstream (ion source-facing) side of sidewall 292 adjacent to beam opening 290. Liner 320 is located on a downstream (substrate-facing) side of sidewall 292, adjacent to beam opening 290. End liner 330 is located on an end sidewall of end station 211, past workpiece 138 and platen 295. Side liners 332 are located on lateral sidewalls of end station 211, lateral to workpiece 138 and platen 295. Additional liners (not shown) can also be located at top or bottom sidewalls of end station 211.

1. An apparatus comprising:
a vacuum chamber, and
a liner having a surface exposed to an interior of the vacuum chamber, wherein the surface is made of porous inorganic carbonaceous material.

2. An apparatus of claim 1 wherein the porous inorganic carbonaceous material has an open pore structure.

3. The apparatus of claim 1 wherein the surface comprises macroporous surface openings having a pore size of greater than 10 microns.

4. The apparatus of claim 1 wherein the porous inorganic carbonaceous material has a thickness in a range from 500 to 1,000 microns.

5. The apparatus of claim 1 wherein the porous inorganic carbonaceous material has a porosity in a range from 18 to 97 percent.

6. The apparatus of claim 1, wherein the liner comprises:
the surface on a first side of the liner,
a second surface on a second side of the liner, and
a thickness between the first surface and the second surface,
wherein the porous inorganic carbonaceous material has an open pore structure, with the open pore structure extending from the first surface to the second surface.

7. The apparatus of claim 1 wherein the porous inorganic carbonaceous material is woven carbon or graphite fibers.

8. The apparatus of claim 1 wherein the porous inorganic carbonaceous material is inorganic carbonaceous foam.

9. The apparatus of claim 1 wherein the porous inorganic carbonaceous material is graphite foam.

10. The apparatus of claim 1 wherein the porous inorganic carbonaceous material is silicon carbide foam.

11. A vacuum chamber that includes an interior and a liner at the interior, the liner having a surface exposed to the interior, wherein the surface is made of porous inorganic carbonaceous material.

12. The vacuum chamber of claim 11 wherein the porous inorganic carbonaceous material has an open pore structure.

13. The vacuum chamber of claim 11 wherein the surface comprises macroporous surface openings having a pore size of greater than 10 microns.

14. The vacuum chamber of any of claim 11, wherein the liner comprising:
the surface on a first side of the liner,
a second surface on a second side of the liner, and
a thickness between the first surface and the second surface,
wherein the porous inorganic carbonaceous material has an open pore structure, with the open pore structure extending from the first surface to the second surface.

15. A method of using an apparatus having a vacuum chamber that includes a liner, the method comprising:
generating an ion beam within the vacuum chamber, or
generating debris particles within the vacuum chamber, or
generating an ion beam and debris particles within the vacuum chamber, wherein
the liner has a surface exposed to an interior space of the vacuum chamber, the surface being made of porous inorganic carbonaceous material, and
during the method of using the apparatus, the ion beam or the debris particles contact the surface of the liner.

16. The method of claim 15:
the ion beam is directed orthogonally at the liner, and ions that impinge onto the liner surface generate particle debris, and
the amount of particle debris generated by the ions is less than an amount of particle debris that would be generated by the ions impinging upon a liner that does not have the surface made of porous inorganic carbonaceous material.

17. The method of claim 15:
the method comprises generating particle debris that enters the interior space of the vacuum chamber,
the particle debris contacts the liner and is captured by the liner and removed from the interior space of the vacuum chamber.

18. The method of claim 15 wherein the liner removes an amount of particle debris from the interior space that is greater than an amount of particle debris that would be removed by a liner that does not have a porous surface.

19. The method of claim 15 comprising implanting ions into a substrate, the substrate comprising photoresist at a substrate surface, the method comprising directing the ion beam at the photoresist and causing the ion beam to generate particle debris derived from the photoresist.
